(19) United States
(12) Patent Application Publication
(10) Pub. No.: US 2011/0159210 A1
(43) Pub. Date: Jun. 30, 2011

(54) Metal halide reactor deposition method

(76) Inventor: Hubert Patrovsky, Ste-Dorothee (CA)

(21) Appl. No.: 12/930,547

(22) Filed: Jan. 11, 2011

Related U.S. Application Data
(63) Continuation-in-part of application No. 11/717,244, filed on Mar. 14, 2007.

(51) Int. Cl. C23C 16/08

(52) U.S. Cl. 427/561; 427/253

(57) ABSTRACT

The invention utilizes a metal halide generating reactor that permits the temperature of the generation of a metal halide from a gaseous halide compound, a halogen gas, or an interhalogen compound at controlled temperatures distinctly different from controlled temperatures of a deposition furnace where metal layers are deposited by CVD processes upon substrates. The method may be further expanded to provide additional layers or reactions on the surface of the substrates with secondary reactions between reactive gases or between species of a metal halide different from the first deposition. Metal halide gases may for example be generated at successive temperatures and with successive different halogen gases or compounds.

### SUMMARY OF INVENTION

This invention provides a method to utilize an in-line metal halide creating reactor to provide specific valenced states of metal halide gases for use in a deposition reaction providing a layer of metal upon a substrate in a deposition furnace different from and at different temperatures from the metal halide creating reactor. The use of the different temperatures facilitates the deposition of metals and the overall process then may allow subsequent modification of these non-oriented amorphous or microcrystalline metal layer(s) deposited upon a different metal (typically steel) by gaseous reactions.

### CO-PENDING APPLICATION

This application is co-pending with application Ser. No. 11/717,244 which is included by reference in this application, and provides the physical means to provide temperature controlled metal halide precursors of this invention.

### BACKGROUND OF INVENTION

CVD (chemical vapor deposition) deposition of a layer of some metals on a substrate is very well established. Other metal depositions are very difficult but the reaction products of these metals may be again easy to deposit. As one example, titanium compound deposition is a series of well established processes and titanium metal deposition is not. Several other metals or metallic compounds also have well established methods of deposition by CVD. For many of the metals above atomic number 22 (Titanium) the methods of deposition of metal layers and compounds have been severely limited by difficulties in the generation of gaseous metal halides on commercial scale. These metal halides, when available were predominately one valence created by one process methodology. The generation of their halides was only the first barrier in depositing metallic layers of other, more exotic metals. These metal halides were very corrosive providing practical problems in their generation, and often not stable or easily obtained commercially. The generated halides and the species generated also may hinder deposition since transport of the halides was quite difficult and optimum halide formation temperatures were often not the same as the optimal or even the practical deposition temperatures.

The use of the chemical vapor deposition (CVD) process itself is well established. Powell, Oxley and Blocher developed the first practical use in the 1880's and shortly thereafter a process was developed using carbonyl decomposition to make CVD coatings. The process was introduced into semiconductor fabrication, crystal formation, and for TiC coatings in the 1960's, and it was used for CVD diamond coatings in the 1980's. The CVD process was further expanded for ceramic and some metal depositions in the 1990's. The technology of CVD deposition is constantly evolving and while some coatings such as Titanium nitride and other titanium compounds are endemic, the process for and use of many other metals have not been explored, largely due to higher costs or to difficulties in formation of precursor gases. The few reported results with the more difficult to handle metal halides have been in lab sized runs that are unlikely to be commercially useful.

The CVD process is defined as the deposition of a solid material or compound on a heated surface from a gas state compound containing the solid material (often a metal) by thermochemical means. This allows deposition on the entire exposed surface of the part, unlike the line of sight depositions in many other processes which use physical vapor deposition (PVD), sputtering or ion implantation and thermal spray processes. Deposition is usually on a disparate substrate but crystal growth of compounds on a seed of the same material is also possible.

The basic advantages of CVD is that it is not restricted to line of sight deposition, it has a high deposition rate which permits thick deposits, and the process is highly adaptable. The process also allows a wide variety of substrate materials which may reinforce the properties of the deposit.

The key factor in the use of CVD deposition has been the thermochemical activity of the gaseous precursors to the deposition process. In general, the CVD process requires a stable precursor that exists as a gas in the temperature range of the initial formation of the precursor and during transport to the deposition target as well as during the thermochemically driven depositions. In many cases the gaseous precursors that would be ideal for deposition have been either non-stable or very expensive. In addition, many of the precursor gases exist in multiple species (valenced) forms but the workable gases cannot be maintained at a stable form for most of these species due to the equilibria variations as the typically high temperatures of formation of some of these species of the metal halides drop or due to the difficulty in formation, vaporization and transport of these gases.

One way to create deposition of metals is to form the metallo-organic (MOCVD) compounds of the metal, compounds that are easy to use in the CVD process and are often stable. The problems with this approach is cost of the MO compounds and the presence of oxygen and organic residues that easily contaminate the metal deposit, thus rendering the metal layer nearly unusable in many cases, and leaving it with vias (gaps or porosity in the deposit). MOCVD is best reserved for formation of oxygen containing compounds where the oxygen is not a contaminant.

Titanium compound deposition is one of the most prevalent CVD deposits. The existence of hard carbides, nitrides, and carbonitrides, have resulted in the use of titanium based coatings for drills, cutting tools and a vast number of other uses. Titanium Chloride (TiCl₄) is stable and easy to use and relatively transportable and cheap. In titanium based coatings this reliance on TiCl₄ has resulted in barring coatings with either an adhesive layer of metallic titanium or with such a metallic layer as part of a series of coating layers. The species TiCl₄ cannot form metallic titanium in CVD deposition due to thermochemical (Gibbs energy) barriers.

While the metallurgical coating industry use of titanium is quite visible, the other large scale use of CVD is hidden inside semiconductors. Here a thick coating is rarely the goal, very thin layers, especially layers that selectively deposit in the desired location to form transistor devices, capacitors, or conductors connecting these devices are the goals. Often MOCVD (metallo-organic CVD) is used and silicon may also be a major component in many of these deposits. The fabrication steps to produce insulating, conductive, and semiconductor coatings are part of an integral fabrication system. Key are the limited number of materials and thin coatings required as well as use limited to electrical properties.

Recent advances in the production of metal halides has enabled further exploration of CVD deposition. Thick layers are possible with a few metals. There still are currently a number of metals where commercial processes for metal layer deposition or compounds of the metal have been impracticable. There are significant possible markets for some of these presently impractical unused metal coatings.

Another seldom explored area is the effect of use of depositions from differing species of a metal halide since the provision of reliable amounts of these species has been very difficult or impractical.

Yet another unexplored area is the use of deposited compounds or layers such as the use of titanium metal within multilayer coatings. While the creation of Titanium metal layers has been possible with use of metallo-organics such as tris-(2,2′ bipyridine) titanium at temperatures under 600° C., these deposits have high impurity levels. The other methods used in making metallic titanium use titanium iodides or bromides at temperatures over 1200° C. or the use of magnesium metal to form MgCl₂ in a basically uncontrollable reaction. The difficulties in using these reagents in the CVD deposition process have rendered most Ti metal/compound exploration moot. While there are Titanium metal/Titanium compound combination coatings made with PVD and other processes, these do not have the non-line of sight advantages of CVD.

There is, for one example, a need for a process to produce pure chromium or other metals that, while not as thick as electroplated deposits, is much thicker than the layers used in electronic devices. These layers, if thick and pure, would be useful for medical, frictional and corrosion proofing applications. The present deposition methods are electroplating; usually a producer of environmentally noxious residues, or line of sight methods such as sputtering and PVD that applies metal atoms to the surface of a target part but which create voids and porosity in the deposit. There is not a good chemical vapor deposition (CVD) process for highly pure Chromium deposits where a Chromium compound is dissociated and the metal atoms are deposited upon the part surface. The chemical vapor deposition methods should be nearly residue and contamination free but, obtaining relatively pure deposition of chromium is very difficult due to the highly corrosive nature of the best (halide) precursors, the high temperatures required, the self contaminating (carbon or oxygen containing) precursors, or due to gas interactions (nitrogen). The thermodynamics of the deposition process are also often contraindicated by the thermodynamic requirements for metal halide formation. Most of the metal halides where the metal has an atomic number higher than 22 (Ti) have a variety of halides (different species) and the effects of use of these metal halide species are basically unexplored due to lack of a method to produce and deposit from the specific species of precursor gas.

A further inhibiting difficulty in working with the larger metal atoms in the form of their halide gases is the often extreme corrosivity of many of these halides. While precursor gases of higher atomic weight metals are sometimes obtainable in small quantities for lab scale reactors, deposition of metals such as chromium, where a halide gas is the best precursor, has been hindered by lack of commercial scale metal halide generators. While the need is present, first a usable source of metal halides must be developed for the very corrosive halides and then methods which allow the conditions thermodynamically required to deposit these halides must be found. The present invention solves the process methods of layer deposition while the co-pending application provides the apparatus needed to enable the metal layer depositions.

There is also a need for a source of metallic compounds, especially generation of a metal halide, that is controllable separate from the conditions of a CVD furnace, and that is reliable and simple to use in commercial size CVD systems.

Metal halide generation, especially for those metal halides that are very corrosive or are not especially stable has been a limiting factor in the development of many metallic depositions upon surfaces of substrates. There has been a need for a generator of metal halide gases, most notably those with an atomic number higher than 22, and after such sources are found, a further need is for processes that provide adequate depositions of these metals or their compounds from their precursor halides in a useful manner.

### DESCRIPTION OF INVENTION

A method and process involving the production of metal halides in a precursor formation reactor with temperature controls that provide optimum conditions for the generation of specific species of the halides produced and specific temperatures for generation of these halides which is fluidly communicating with a separate deposition zone located within a separate CVD reactor (furnace) where different temperatures of deposition encourage deposition of metal on a selected substrate different from the deposited metal. This method consisting of a temperature controlled reactor connected to a separately controlled CVD furnace provides for deposition and gives access to methods employing a process utilizing at least dual temperature controls, one for metal halide production and a different one that provides thermodynamically driven depositions not presently available in single temperature halide generating reactor/deposition furnace units and provides depositions resulting in unusual hardness or other properties of selected metal layer depositions. Depositions with multiple layers and with successive series of reactions in the deposition area are also enabled in this invention.

The construction of a metal halide source vessel within an outer housing separate from and separately controllable from a deposition reactor zone or a deposition furnace provided unexpected benefits. The gas formed in such a separate metal halide generator allows not just the formation of the metal halides, but the selection of the conditions for the formation of preferred species of these metal halides. The separation of the formation zone from the deposition zone allows reactions that are impossible within a common generation and deposition zone.

The present invention provides a method of use for a separated metal halide generator for metals that are not presently feasible to use in commercial CVD deposition systems. The method of this invention allows multiple sources for metal compound formation and gasification through reactions that provide reactive metal halide vapor feed to large commercial scale CVD furnaces.

CVD, the chemical vapor deposition method started in the late 80's provided a method for the vacuum deposition of metals free of line of sight restrictions. As the technology advanced the possible products went from simple wear resistant TiN coatings on drills and the like to complex thin layer metal coatings such as used on microchips. The use of titanium and other low boiling point metal halides increased and TiN and TiCN became popular. The stage was set for development of thicker pure metal deposits on parts and while this was possible with the low reactivity easily vaporized compounds of metals—the highly reactive and high temperature reactive metals such as chromium, tantalum and tungsten were not as easily handled and the limitations of precursor metal halide supply prevented the commercial deposition of relatively pure metal layers of many metals which may have desirable properties. This invention provides a method of use of specific species distribution within the metal halide precursor gases selected through temperature control which is possible in multivalenced metal molecules and the subsequent deposition of metal layers from this metal halide species distribution.

Metal halides are an excellent source of reactant for CVD processes due to lack of secondary reactions between metals and halogen and the reactivity at the temperature and pressure dependent decomposition of the metal halide molecule. While there are metal chlorides that are liquid at room temperatures (TiCl₄ for example), and are stable or relatively stable at these temperatures many other halides are highly corrosive and/or exist as a liquid or gas only at high temperatures. The first group (room temp liquids and moderately reactive) are used in many common processes such as formation of titanium nitrides or other titanium compounds. The second group has allowed experimental development work by use of small halide injectors or vaporization cells of various types. The lab sized injectors allow injection within a deposition furnace at furnace temperatures. This invention shows methods of use and processes using specific selection of species of metal halides and the separate temperatures used to form these species within a multistep deposition process where the precursor gas required for deposition is formed separately at separate conditions from the deposition zone and uses different temperatures in a multistep generation/deposition process. The invention further provides for the addition of pre deposition treatments or post deposition treatments, expands the usefulness of the CVD process, and allows depositions not presently practicable.

Before the reasons for use of species or specific halides are discussed, the type of surfaces should be briefly discussed since the chemistry involved in use of specific species and halide compounds enable specific surface formation.

The mechanism of the deposition is critical in understanding the results. For example, some deposition modes seem to orient toward single crystal or larger crystal development while others produce an amorphous or a microcrystalline deposition. Despite the importance, there is little proof of the mechanism of deposition of materials. One school intuits that the actual reactions which result in deposition occur on the surface with one part of the compound attaching to the surface by contact and forming a reactive point upon the surface then reacting with the second ion of the compound to neutralize the atoms thus forming the full compound. Another view is a reaction that occurs above the surface and then “drifts” or is electrically forced onto the surface being coated.

Visualizing the reaction as a combining of ions formed by thermochemical degradation of a gaseous compound, the materials combine and react slightly above the surface in a hot (or cold) layer running around the part, this layer being an artifact of the deposition temperature which causes the thermochemically activated degradation of the gaseous compound. This degradation and/or recombination occurs at or above the surface of the part being coated and the fully reacted or neutralized compound or metal falls to the surface where it is attached by conformation with the surface. Such a mechanism is ideal for large crystal formation where the formed molecules drop into spaces within the crystal network.

In this invention, the goal is a smooth surface that is essentially free from the tennis ball like formations that cause breaks in the coatings and greatly increase the frictional coefficients of coated sliding surfaces. By a smooth surface a Frank-van der Merwe deposit surface (FM: layer growth) as opposed to a Volmer-Weber (VW: island formation) or Stranski-Krastanov (SK:layer plus island growth) is described as “ideal”. For such a smooth surface a deposition on the substrate surface is positied and this, especially for metals, results in a layer by layer (FM) deposition mode.

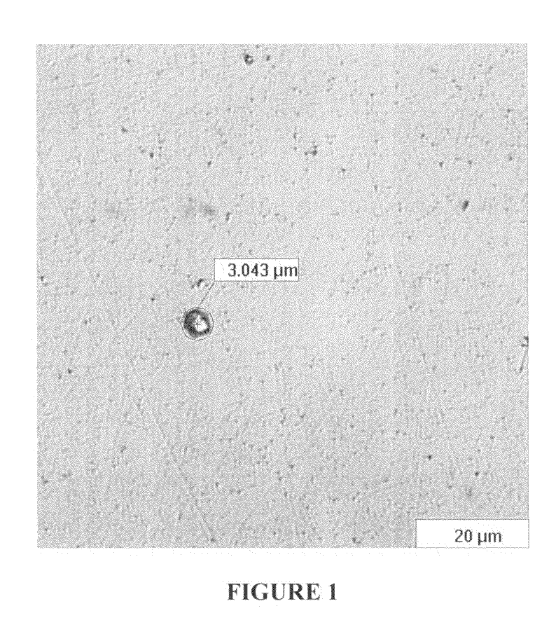

Layer growth on an initial uniform wetting layer will provide a smooth surface that closely replicates the surface of the substrate. Problems start when VW type deposition starts either on the substrate or SK growth on the deposited FM layers and the resulting seeded growth creates high spots in an otherwise smooth layered surface. These growths, frequently called “tennis balls” seem to coalesce around a “seed” and the resulting growth outward from the surface is shown as the “tennis ball” phenomena. This phenomena is shown on a surface of Titanium compound layers in FIG. 1. It soon becomes evident that for an antifriction surface or a hard cutting surface, the worst possible coating outcome is a surface with detectable projections such as crystalline growth on seed particles which can tear off or chip and create abrasive particles on the smooth surface. To prevent this, the surfaces are of dissimilar materials and the coatings are laid down in a surface tacked manner thus preventing the formation of obvious crystals. While it could be argued that a single perfect crystal would be an ideal coating, our technology is a long way from this goal so keeping the surface as flat and crystal growth free (FM deposition) as possible becomes the best alternate.

In one case, that of Titanium deposition, use of this invention permits the deposition of a metal layer of titanium as a wetting layer on the substrate by use of high temperatures of reaction and an HCl starting chlorine reactant making predominately TiCl₂ as the reactive metal halide, then switching the reactant feed in the metal halide formation reactor to lower temperatures and reactant of Cl₂ and then using the TiCl₄ metal halide gas thus formed, in the presence of nitrogen, to create subsequent layers of TiN or other Titanium compounds (with their required co-reactants). The metal wetting layer may limit the formation of tennis balls as the deposition goes from 2D to 3D (thicker total deposition) and the metal layer provides superior adhesion.

The surface that is created by reactions should make a metal layer on a surface that is basically flat and smooth. The problem often found is that a sprinkling of “tennis balls”, microscopic (on the order of 1 to 4 micron size) protrusions from the surface form on particles or flaws in the substrate. This is a VW type growth. These balls, presumably the start of crystals, while not common, are a disaster to applications requiring sliding surfaces. The goal of the metal or compound layers are thus to eliminate all crystal growth and keep layer formation at a amorphous or microcrystalline level layered FW growth. For ideal control, the control of mode of deposition shown herein which is aided by control of metal vs compound initial depositions and by selection of species for specific thermochemical reactions, is a major improvement in smooth amorphous or microcrystalline layer creation. In most cases the layer in fact may be amorphous or microcrystalline but it remains flat and microcrystalline layers do not seem to provide bases for either VW or SK growth as seed crystals would.

Now, knowing that a flat multilayer surface—microcrystalline or amorphous in nature—ideally of metal is desired, let's look at the thermochemistry in this invention that can enable such a layer.

The selection of species (valences) among the different halides of a given metal is used in this invention both in the formation of compounds that are precursors to the deposition process at the reactor site and in the specific deposition modes within the deposition furnace. This allows selection of specific reactions, especially in deposition of metallic coatings. The description below provides background on how Gibbs Energy (Gibbs free energy, AG) affects the present invention, an important concept in the understanding of how specific metal depositions are enabled in this invention.

The most important feature of this deposition method is the employment of external heating of the precursor forming reactor and the separation of this reactor from the deposition reactor (furnace) heating and the effects of this separation. Each reactor is separately controlled so temperatures of each may be maintained at different levels. This allows employment of different precursor formations and deposition temperatures which in turn permits partial control over reaction equilibria resulting in the provision of different species (products of the reaction in the precursor gas formation reactor) and transport to a deposition area in a deposition furnace at a different temperature. This allows the driving thermochemical affinities of both the precursor gas generator and of the deposition site in the deposition furnace to be optimized or controlled for specific reactions. It further allows the effect of entropic energies to be utilized due to the temperature differences between gas formation and gas deposition reactions.

Let's consider the reaction:

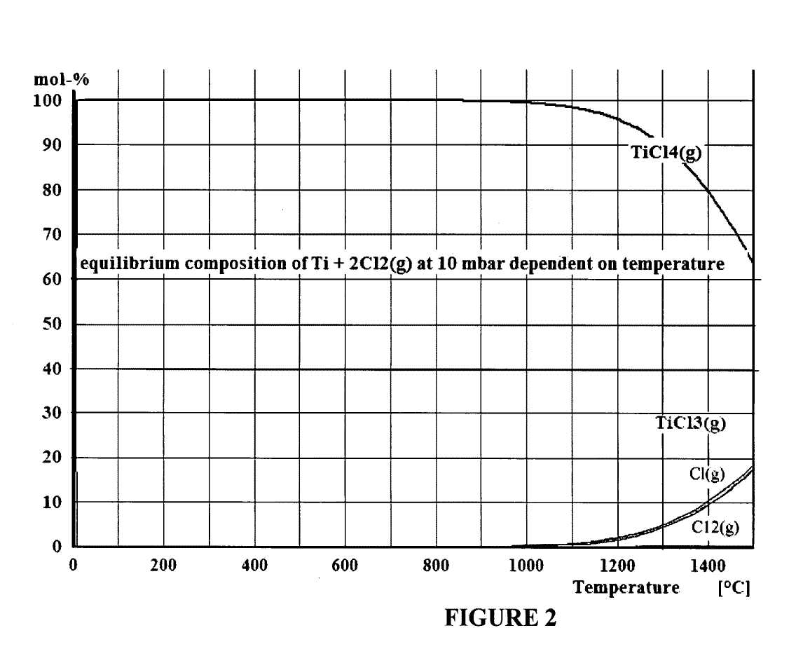

Ti+2Cl₂(g) [symbol] TiCl₄(g) (1)
with (at 0° C.)
ΔH_{R}=−182.413 kcal/mol (enthalpy)
ΔG_{R}=−174.326 kcal/mol (Gibbs)
ΔS_{R}=−29.605 cal/mol/° K (entropy)
   First looking at the enthalpy of the reaction with a Titanium metal or compound deposition, we see that the enthalpy of the reaction grossly favors the formation of TiCl₄ as the reaction product within the precursor gas reactor portion of the CVD system. Thus variation on the temperature of the precursor gas formation reaction will have essentially no effect on the relative share of this gas (or its species as shown in FIG. 2). Further obscuring the positive effects of the present invention, the enthalpy of the TiCl₄ decomposition and the reformation as a metal is resoundingly positive (doesn't freely occur). As a result the potential for deposition of metallic Titanium is near zero. As shown in FIG. 2 for the reactants Ti+Cl₂(g) at 10 millibars, the other Titanium Halides are nonexistent until a trace of TiCl₃ is noted above 1100° C. (These calculations were done with software HSC 6.1 (Outokumpu Research Oy, 2007)). Since TiCl₄ is so dominant a reaction, information of deposits on metallic Titanium from different species is also nonexistent. As a result of these enthalpic limitations with Titanium and its halides the reaction:

TiCl₄(g)+½N₂ [symbol] TiN+2Cl₂(g), (2)

one of the most common and most investigated CVD deposition methodologies, proceed at a wide variety of metal halide formation temperatures in exactly the same manner. Since the titanium halide TiCl₄ is readily available, a reactor for their generation is not used in practice, but if one would be used, regardless of the precursor gas formation temperatures and the deposition temperatures, as determined by their enthalpies (Gibbs free energy) and independent of the effects of the relative temperatures, the result would be the same. Thus, due to the uniform single mode of metal halide formation and the strong driving force of the compound formation, only TiCl₄ is formed and is the only precursor gas used in titanium compound deposition reactions. Titanium metal cannot be deposited. With other metals and their halides this is not true. This difference is very important in the application of the Patrovsky method of deposition within CVD furnaces.

With most multivalenced compounds, especially those with atomic numbers above 23 (Ti is 22), the enthalpy and entropy interchanges are very different. There are, in most cases, several species of metal halide formed at different conditions and unlike the Chlorine gas generated TiCl₄ which is almost universally used and the reactions for deposition of Titanium compounds that result, these reactions, while at equilibrium with each other, have some equilibria showing deposition from more than one species. As one example we will later examine Chromium (atomic number 24). The commonly known technology used with TiCl₄(g) obscures and ignores the effects of species of halide precursor gas we find to be very important tools and ignores the entropy of the deposition process since prior technology has heating limitations and does not clearly separate the temperature effects (often influenced by the reaction entropy) of the halide formation and the deposition areas. In Titanium compound CVD depositions to date, other gaseous Titanium halide species such as TiX₃(g), TiX₂ (g) or TiX(g) can be ignored totally in the formation of Titanium halides since, below 1500° C. (see FIG. 2), there is essentially no gas present except the TiCl₄(g) species. Unexpected positive results of temperature effects are found in the application of entropically influenced depositions in many other multivalenced metals. Prior technologies and patents ignore and did not realize the possibility of such precursor gas creation and deposition differences as influenced by the respective temperatures of the gas formation reactor and the substrate in the deposition reactor (furnace).

The enthalpy of the halide formation reactions, ΔH is the amount of energy or heat absorbed or released in a reaction at constant pressure. Standard enthalpies are available for many compounds and can be calculated. In short, the enthalpy of a reaction is the net of the sum of the products of a reaction minus the sum of the reactants of the reaction;

ΔH_{R}=Σ(H_{products}) [symbol] Σ(H_{reactants}) (3)

Analogous relations hold for the entropies and free Gibbs energies of reaction. These thermodynamic variables are interrelated by the equation:

ΔG_{R}=ΔH_{R}−TΔS_{R} (4)
with T in ° K
   The standard enthalpies, entropies and corresponding free Gibbs energies are mostly given in literature. Values can be compared at standard conditions (0° C.). As such, the enthalpy is a large factor, the temperature effect often makes the TΔS term somewhat relevant despite the much smaller values of ΔS. As high temperatures are used in a reaction, the basic reaction is more and more weighted toward the entropic term in the equation. At temperatures around 1000 degrees C. or above entropy has a dominant effect.

Now looking at the path not taken in Titanium depositions, the side effect of generation of a metal halide gas through the reactions accompanying the main reaction of;

Ti+4HCl(g) [symbol] TiCl₄(g)+2H₂(g) (5)

are the following:

2Ti+6HCl(g) [symbol] 2TiCl₃(g)+3H₂(g) (6a)

and

Ti+2HCl(g) [symbol] TiCl₂(g)+H₂(g) (6b)

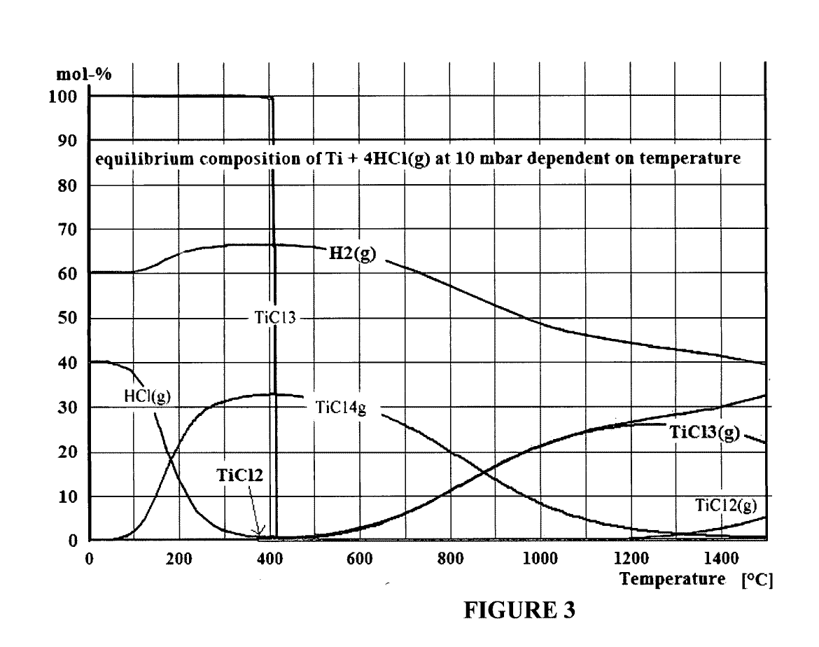

which is shown in FIG. 3 where the equilibrium at 10 mbar is shown at various temperatures. As the FIG. 3 shows, by variation in the temperature of the metal halide generation reactor a variety of different ratios of the species Ti(IV), Ti(II) or Ti(III) are possible and these differing ratios based upon a reaction providing differing Gibbs potentials, provide additional deposition possibilities within a deposition furnace which has its own (different) temperature causing depositions.

While the HCl based reaction is not used in commerce, this sourcing of the metal halide via the hydrochloric gas reaction with Titanium provides a vastly different Gibbs reaction result which enables a metal layer deposition in the deposition furnace at certain deposition temperatures. Now CVD may obtain the base previously restricted to the metal deposition ability of the PVD process and then can further vary the surface of the metallic deposit with other compounds by secondary additions of reactants. In most cases the secondary reactant additions will be preceded by a purge to separate the reactions so that distinct layers are deposited or formed on and in the Titanium metal layer.

Provision of such a metal base for the hard and brittle layers of TiN, TiB, TiAlN or TiCN or a combination of these layers may add crack resistance and deter loss of adhesion in the hard layers. The secondary reaction of the metal layer to a compound may also drastically change the nature of the compound, creating a surface layer under compression.

Now dealing with the added entropic effect and using Gibbs as a indicator of the driving forces within a given set of reactions in other metals and their metal halides, we see that curves may be generated at different temperatures and for different valenced species (i.e. for different entropy conditions) that give equilibrium compositions that are weighted differently, thus the products of formation or deposition vary with these curves and with the temperatures which cause the entropic differences. The discussion below provides additional examples.

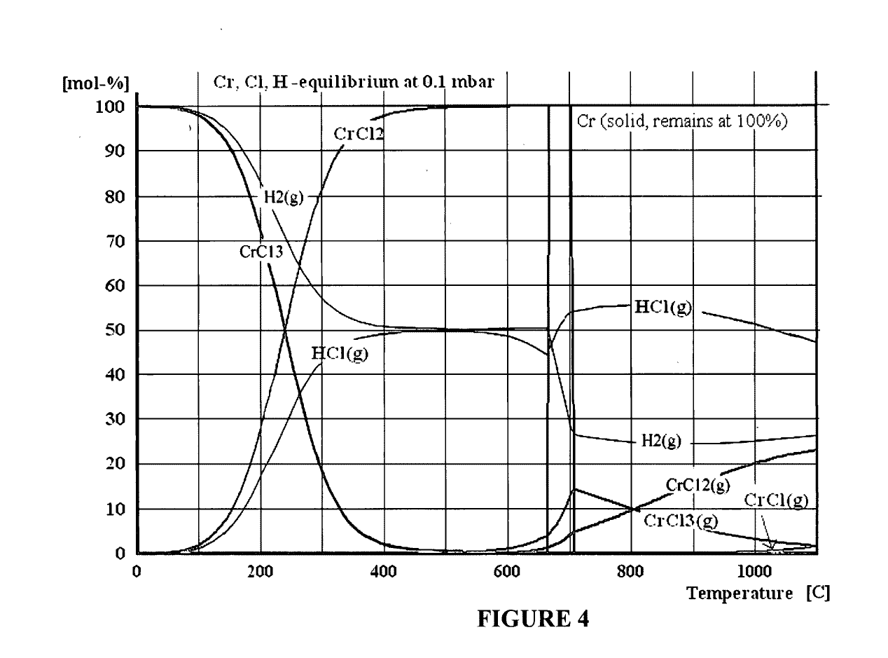

Now looking at the Cr, Cl, H equilibrum curve in FIG. 4, which shows calculated temperature dependent equilibrium composition of a reactive mixture prepared from 1 mol chromium (Cr) and 3 mol hydrogen chloride HCl(g) at 0.1 mbar. At above 650-700° C. there is an equilibrium between solid chromium and gaseous Cr(II) chloride CrCl₂(g), Cr(III) chloride CrCl₃(g), HCl(g) while above 1000° C. there is also gaseous Cr(I) chloride CrCl(g). Note that at 700° C. and above, the relative amounts of CrCl₃(g) decrease and of CrCl₂(g) increase with further increasing temperature. These calculations were done with software HSC 6.1 (Outokumpu Research Oy, 2007). In these calculations, if there is solid chromium in the mixture the calculation represents it with 100 mol %, irrespective of the shares of chromium in the other chromium compounds.

The higher the temperature at the deposition site (the CVD furnace) the more the indiffusion of the first deposited metal atom into the surface of the target substrate which can be very advantageous

Interpretation of the FIG. 4 would indicate that, in a reactor filled with chromium metal (Cr) granulate and penetrated by a flow of gaseous hydrogen chloride HCl(g) at 0.1 mbar above 700° C. gaseous Cr-chlorides are formed. As a result, the following would be controlling:

(1) For the deposition of chromium on targets at 0.1 mbar and at temperatures not much higher than 700° C. the precursor gas reactor has to be driven at higher temperatures to get maximum yield of CrCl₂(g) in the product gas stream because this chromium chloride will in turn decompose at targets of temperatures slightly below the precursor gas generation temperature (i.e. around 700° C.).

(2) On the other side: For the deposition of chromium on targets at 0.1 mbar and at temperatures much higher than 700° C. (e.g. at 1000° C.) the precursor gas reactor has to be driven at temperatures at temperatures slightly higher than 700° C. to get maximum yield of CrCl₃(g) in the product gas stream because this chromium(III) chloride will in turn decompose in the deposition furnace on targets of temperatures much higher than the precursor gas reactor temperature of around 700° C. Thus the conditions for the metal halide forming reaction formed from elemental gaseous halides (X₂(g)) as well as from the gaseous hydrogen halides HX(g) effect the decomposition at a deposition site with temperatures different from reactor temperatures.

While the variations in the amounts of different species explained above and the experimentally noted fact that different species in depositions provide variations in surface hardness in chromium and probably other different characteristics in the micro-crystallography or the amorphous nature of the deposits, the fact of separation of heating ability in the precursor forming reactor and in the deposition furnaces allow different deposition processes and in some cases allow depositions not presently possible with more uniform temperatures between precursor gas formation and CVD deposition temperatures.

One of the critical concepts in this invention enabled by separation of the temperatures in the precursor gas formation reactor and in the deposition furnace is that this change provides the process with a Markov like property where the reactions are subject to a conditional probability that is temperature dependent in each part—the formation of precursor gas and the deposition of a compound or metal from that precursor gas. This hewing to the Markov type chain concept is totally absent in all other noted CVD deposition systems since they have an unchangeable precursor gas formation temperature that is closely related to the deposition temperature. This unchangeable gas formation and gas deposition condition(s) results in one or at most a very narrow set of results. A deposition comes from one species of generated precursor gas since the use of Titanium halide as a readily available precursor halide and the single or very narrow temperature variations in formation/deposition reactions can only form the precursor at or near only one set of equilibria since the temperatures of precursor formation and deposition reactions are chained together by mutual heating systems. The differential and conditional precursor formation in the present invention gives a set of temperature function results that provide a choice of equilibrium points within the formation curves at different temperatures that provide different ratios of the species (valenced) gases formed. In a similar manner the deposition, which is also a function of the temperature (entropic effects) of the decomposition reaction is controllable in part by temperature and may be very different from the temperature effects on the precursor gas formation. Thus, the precursor gas formation temperature choice will in turn affect the next process in the series—that of the deposition process where the temperature is also selectable.

This method or process is different in permitting the partial control over the species involved in both gas formation and gas deposition modes when depositing metals. It may also permit the deposition of metals where the more common species (of chlorides and other reactive metal containing gases) are entropically adverse to a metal deposition reaction. The reason for the extra effort of separation of the temperatures (entropic contributions) of the gas formation results in unexpected properties. The work of Patrovsky shows in the chromium infusion into and the deposition of Chromium metal layers upon a cobalt rich substrate that there is a significant difference in characteristics of the deposits such as rate of infusion and deposition and crystal structure and hardness as the species created in the formation of precursor gas is varied. The infusion and deposition temperatures likewise when they are varied from the temperatures of the gas formation also deposit pure metal but with variable hardness that, at times is much greater than expected.

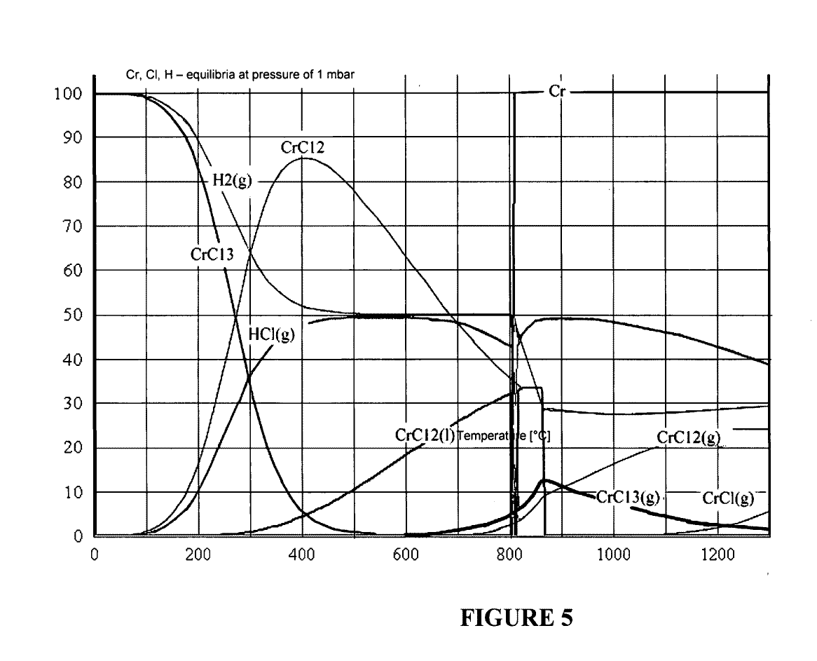

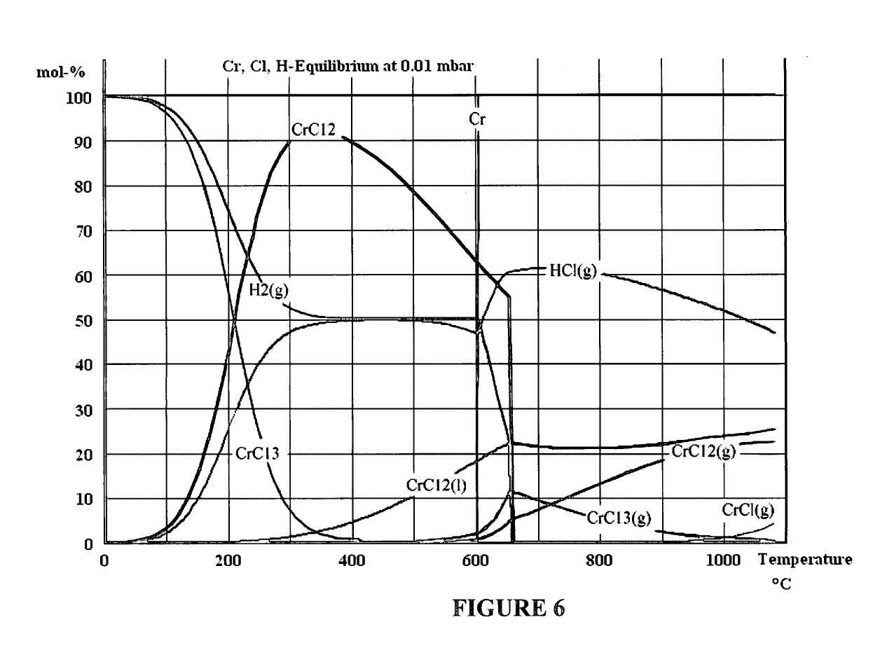

Simplifying the above discussion, looking at the attached curves (FIGS. 5 and 6) for different pressures over a range of temperatures, at each given pressure the amount of CrCl₂(g) increases with increasing temperature compared to CrCl₃(g). Looking at the different pressures, the lower the pressure the more CrCl₃(g) compared to the amount of CrCl₂(g) over the range of temperatures where both gases are present. Unfortunately where the precursor gas reactor and the deposition furnace are coupled in fluid communication, this effect of different pressures is very difficult to utilize. Thus the Patrovsky inventions ability to regulate and control the temperature of both the precursor gas formation reactor and the deposition furnace at temperatures that differ gives one of the few possible ways to control thermodynamic relationships within each of these elements of the process and to take advantage of an ability to change the species of the gas being deposited within the deposition area of the deposition furnace.

The reason for the foregoing proportions of the respective species of Chromium Chloride is that the entropy (ΔS_{R}) for the formation of CrCl₂(g) from Chromium metal and HCl(g) is slightly positive—about +6 cal/° K between 100 and 1000° C.—while the entropy (ΔS_{R}) for the formation of CrCl₃(g) from Cr metal and HCl(g) is slightly negative between 100 and 1000° C.—about −7 to −10 cal/° K. Qualitatively, the reason for the changes in entropy are the changes in the number of gaseous molecules in the system [Cr metal, HCl(g)] which decrease from 3 to 2.5, giving a trend towards decreasing entropy with the reaction to CrCl₃(g) [Cr+3HCl(g)→CrCl₃(g)+1.5 H₂(g)] whereas it remains constant, thus producing only small entropy changes, with the reaction to CrCl₂(g) [Cr+2HCl→CrCl₂(g)+H₂(g)]. Thus, the reaction to chromium (III) chloride is preferred at lower pressures (it loves higher vacuum).

While lower pressure has an effect increasing CrCl₃ in the reactions, there is a countering positive heat term, ΔH_{R}, of about 12 kcal/mol for the reaction to CrCl₂(g) from Cr and HCl and a negative heat ΔH_{R} term of about −12 Kcal/mol for the reaction to CrCl₃(g). So the reaction to CrCl₂(g) in essence loves heat (it consumes heat) but the reaction to CrCl₃(g) produces heat and does not need more heat (i.e. higher temperatures) to increase its share of the reaction to CrCl₃.

Since the reaction of the pressure effect is overwhelmed by the effect of the temperature, especially as temperature rises to levels where the chromium halides are gaseous, the result is clearly shown in the FIGS. 4, 5, and 6 where the difference in CrCl₂ levels and CrCl₃ levels changes as the temperature rises thus allowing a choice of the valence of the precursor gas formed in the reactor that is controlled at temperatures different than the temperature of the deposition furnace which allows metal depositions not possible with other metal halide generating systems or apparatus. At 660 degrees the ratio is 2 parts Cr(III) to one of Cr(II) while at 900 degrees the amount is varied to 1 part of Cr (III) to nearly 6 parts of Cr(II) at a constant pressure of 0.01 mbar. At reactor temperatures around 1000° C. there is also Cr(I) present. In the cited Figures the effect under discussion is further highlighted by examination of the relative amounts of each species at each temperature (i.e. amount in mol % of one species divided by the amount of the other species in mol %).

In corrosion resistance uses, a metallic layer of tantalum would provide a surface protection exceeded only by a gold or platinum barrier. As is well known, the metal tantalum (Ta) is known as a chemically very stable metal against most nonoxidizing acids. It is experimentally well known that it is attacked only by
Hydrofloric acid (HF),
a mixture of oxidizing acid as HNO₃ or Oleum with hydrofluoric acid (HF),
a melt of alkali hydroxides,
gases like X₂ (X=F, Cl, Br, I),
with Cl₂ above 300-350° C. and with dry HCl above 350-410° C. gaseous TaCl₅(g) is formed. At higher temperatures TaCl₃ will be formed which is not as volatile as TaCl₅.
O₂ at high temperatures above 1000° C.
   The reason of this stability is not that Ta has to be considered as a precious metal like gold or platinum but the reason is the dense and chemically very stable oxide layer consisting of Tantalum(V) oxide (Ta₂O₅). So, a chemical attack on to Ta-metal is prevented provided the attack on its oxide layer is not enabled. In normal applications in air, any damage to the oxide layer would be self healing as another layer of oxide rapidly forms. The decomposition of TaCl₅ in the presence of water vapor into Ta₂O₅ and HCl is a process used for industrial CVD and PVD of Ta₂O₅ as an isolating layer with high dielectric constant (−26) instead of SiO₂ (−3.9) on silicon wafers in electronics as well as a coating layer of high refraction index in optics (antireflection layers). In fact, the tantalum compound is used as tantalum pentaethoxide (Ta(OC₂H₅)₅) which is stable in storage and not particularly toxic. This use of tantalum is as an oxide forming an insulating layer and in DRAM capacitors and creates only oxide(V) layers. Using the already oxidized Ta in the pentaethoxide compound makes oxide layer depositions easier and avoids the problems in forming less stable and difficult metal halide forms that are solved in this multistage invention.

It is well-known that the Tantalum(V) oxide (Ta₂O₅) dissolves in molten alkali hydroxides, alkali hydrogen sulfates and molten sodium carbonate—but not in acids with exception of concentrated HF. It is also known to be attacked by gaseous Cl₂ and gaseous HCl at temperatures above 1000° C. at normal pressure and if gaseous TaCl₅ passes over Ta₂O₅-surfaces at 600-1000° C. then white sublimates TaOCl₃ and TaO₂Cl are precipitated downstream. Further on it is known that in vacuum at temperatures above 1470° C. Ta₂O₅ (mp. 1872° C.) decomposes into Ta and O₂, releasing gaseous TaO and TaO₂.

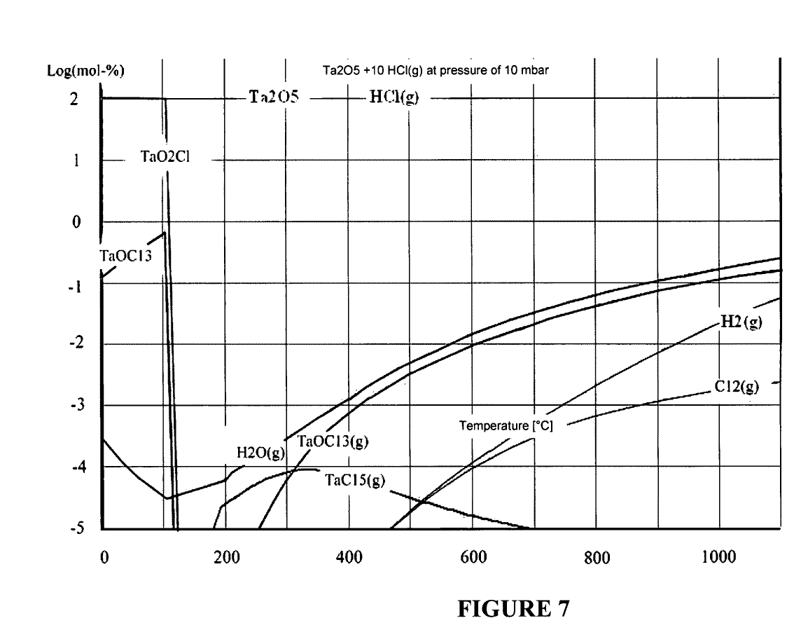

Therefore the system solid Ta₂O₅: gaseous HCl [Ta₂O₅(s): HCl(g)] between 0-1100° C., at 100, 10 and 1 mbar overall pressure and with the two molar ratios 1:10 and 1:2 is considered at first (FIG. 1) and then the system elemental Ta (i.e. the pure metal not covered by an oxide layer) and dry gaseous HCl will be considered (FIG. 7).

As shown in FIG. 7, the Ta₂O₅-layer is attacked above ˜200° C. by gaseous HCl according to the 2 reactions

Ta₂O₅+8HCl(g)←→TaOCl₃(g)+TaCl₅(g)+4H₂O(g) (5)

and

Ta₂O₅+10HCl(g)←→2TaCl₅(g)+5H₂O(g) (6)

proceeding to a higher extent from left to right for reactions (5) and (6) with increasing pressure. Further on there are the hypothetical reactions below 100° C., which are calculated to proceed if HCl(g) is in excess to the oxide but which are not known to proceed experimentally with solid oxide in this temperature range:

Ta₂O₅+6HCl(g)←→TaOCl₃+3H₂O, (7)

Ta₂O₅+2HCl(g)←→2TaO₂Cl+H₂O. (8)

Above its maximum at 500-300° C., dependent on pressure, the formed TaCl₅(g) starts to decompose into the oxide and HCl in the presence of water vapour according to the reversed reaction (6). Another reaction decomposing TaCl₅(g) in the presence of water vapour above 400° C. is reaction (9)

TaCl₅(g)+H₂O(g)←→TaOCl₃(g)+2HCl(g), (9)

and this equilibrium shifts to the right with increasing temperature.

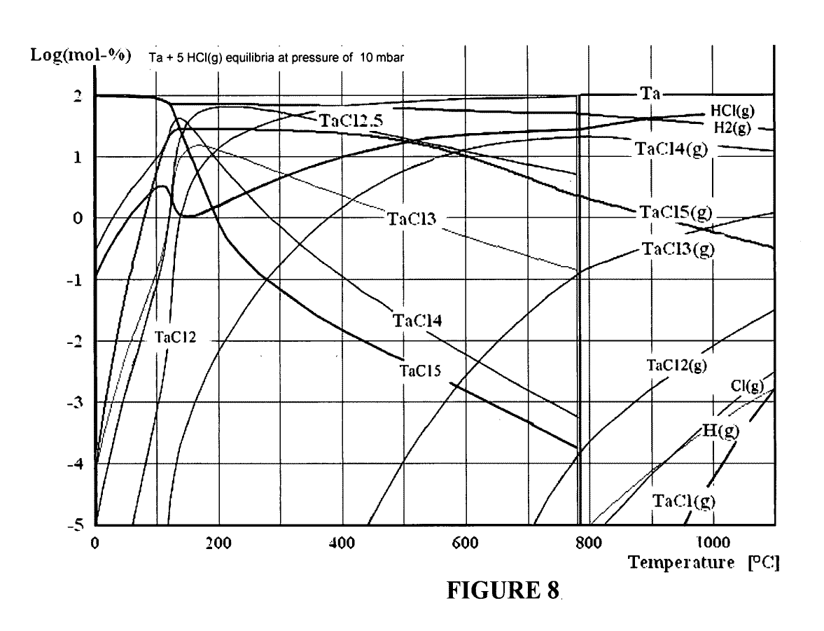

From FIG. 8 it is clear that after having removed the oxide layer the metallic tantalum forms different chlorides in an HCl-atmosphere—among them the gaseous TaCl₅(g) already at low temperatures of ˜200° C. at 100 mbar and at ˜100° C. at 1 mbar:

Ta+5HCl(g)←→TaCl₅(g) (10)

Ta+3HCl(g)←→TaCl₃ (11)

and the other solid Ta(II, IV)-chlorides also.

From experiments at normal pressure the reaction (10) is known to proceed at 350-410° C. already. This means an eventual reactor could be held at normal pressure at these temperatures and the formed TaCl₅(g) can be sucked into the CVD-furnace by its vacuum.

On the other side FIG. 8 shows that the deposition of Ta at substrates proceeds by thermal decomposition of TaCl₅(g) at hot substrate surfaces at more than ˜920° C. at 100 mbar and at more than ˜680° C. at 1 mbar.

The yield of this thermal decomposition increases with further increased temperatures of the substrates.

Now, taking both reaction schemes for the forming and thermal decomposition of TaCl₅(g) according to reaction (10) and the reaction between TaCl₅(g) and H₂O(g) according to reaction (6) together it is clear that the conditions have to be optimized for the reactions (10) and (6) to proceed as the dominating ones and one after the other:
1. Removal of oxides to enable metal halide formation
2. introduction of chlorine containing compound to precursor generation furnace and metal halide formation at a first temperature
3. Transport of resulting metal halide to alternate furnace (deposition area) where substrate parts are loaded and which is maintained at a second temperature
4. Deposition of metallic Ta,
5. Introduction of additional reactive gases (optional)
6. Addition of O₂ or H₂O
7. Reaction to Ta₂O₅ on the deposited Ta-metal and stabilizing the deposited Ta.
8. Cool and remove parts

For this purpose it is proposed to start with HCl and to generate TaCl₅(g) from the halide formation reactor, to transport it to the deposition furnace (reactor) and to mix additionally water vapor in the final phase of the coating. This must be a three to seven step process with the difficult part obtaining the metallic tantalum layer, then the oxidization of this layer. The most critical steps are—the removal of the Ta₂O₅ layer with exposure to hydrogen chloride gas at temperatures in the 300 to 500 degree C. range optimum for oxide layer removal, then, after purge of the chloride forming reactor, the formation of tantalum chlorides in the range of 350 to 410 degrees C. followed by the transport of this TaCl₅(g) gas into the deposition reactor where parts (substrate material) are heated to above 1000 degrees C. where Tantalum metal should deposit. In a final step, at lowered temperatures in the deposition reactor water vapor is introduced after a further purge and the oxide layer is formed over the metallic tantalum layer.

The usual process using tantalum is the industrially used decomposition of TaCl₅ in the presence of water vapor into Ta₂O₅ and HCl for industrial CVD and PVD of Ta₂O₅ as an isolating layer with high dielectric constant (−26). Placing a similar isolating layer over metallic tantalum provides a self healing corrosion resistant layer that has a number of positive properties such as biocompatability.

The process of this invention permits the creation of a metallic tantalum layer by production of the tantalum chlorides at a temperature that is optimized for this process then flushing or pulling the chlorides thus created into the deposition reactor that is maintained at a much higher temperature optimized for the specific deposition of the metallic tantalum. In a later step the introduction of water molecules at a temperature further optimized for the driving of oxide layer formation provides the corrosion barrier over the surface of metallic tantalum. In this array of conditions, at least two different temperatures are used within the deposition reactor while separate tantalum chloride reactor temperatures and water vapor inputs are used. Without the temperature differences between the temperatures of the Tantalum chloride generating reactor and the tantalum deposition reactor, the process would either not result in metallic tantalum deposition (deposition reactor too low in temperature) or the reactor would not generate the TaCl₅ (g) (formation reactor too high in temperature), the species required for the deposition of Tantalum at the target substrate.

Looking again at the reaction schemes for the forming and thermal decomposition of TaCl₅(g) according to reaction (6) and reaction (2) it is clear that the conditions need to be optimized for the reactions (6) and (2) to proceed as the dominating ones, but other reactions can also be used with alternate steps added. These steps must be sequential. This gives the following as minimal required steps in addition to the normal loading, vacuum establishment, purging and unloading steps:
1. Load parts into a deposition furnace, then remove oxides and contaminants on parts within the deposition reactor by chemical vapor etch or physical sputtering, then,
2. Start Metal halide formation in a metal halide producing reactor at a desired temperature, and convey this halide to the separate deposition furnace in step 1, then
3. Deposit metallic Ta from the metal halide at a deposition temperature in the deposition furnace,
   The last step above can also be modified to provide other results—the disilicide of Tantalum may be formed on the surface of the metallic tantalum by adding after step 3 the new steps 4, 5 and 6. Specifically:
4. Reduce heat in deposition area of the deposition furnace to under 540° C. and purge the furnace, then
5. Introduce into the deposition furnace Silane gas (SiH₄) to react a TaSi₂ layer
6. Cool down and increase pressure to ambient and unload furnace

For this purpose it is proposed to have an additional input to the deposition area of the furnace and the coating of TaSi₂ which is useful as highly corrosion resistant, is refractory with very low electrical resistivity. The multistages permissible with the invention and the separation of the main precursor formation reaction(s) from the deposition zones and the deposition conditions provides a flexibility that is not generally available in the present deposition reactors. Allowing the formation of tantalum chlorides in the range of 350 to 410 degrees C. followed by the transport of this TaCl₃ gas into the deposition reactor above 1000 degrees C. where Tantalum metal will form, then cooling this deposition reactor and further reaction steps to convert part of the metallic coating formed at higher temperatures to yet another protective coating within the deposition furnace allows clean effective delivery of multiple layered coatings not presently available.

### DESCRIPTION OF THE DRAWINGS

In FIG. 1 a microphotograph of a “tennis ball” crystallite structure is shown on an otherwise smooth metal deposit surface. The ball is just over 3 microns in diameter.

In FIG. 2 an equilibrum chart for the reaction of Titanium with chlorine gas is shown over a temperature range up to 1500° C. at a constant pressure of 10 millibar.

In FIG. 3 an equilibrum chart showing the many species of Titanium chlorides reached at various temperatures after reacting Titanium with hydrogen chloride at a pressure of 10 millibar.

In FIG. 4 an equilibrum curve similar to that in FIG. 3 is shown for the chlorides of Chromium at a pressure of 0.1 millibar. Multiple species of chromium chloride vary in percent content as a function of temperature.

In FIG. 5 the curve and equilibrum conditions similar to those in FIG. 4 are shown with the pressure increased to 1 millibar

In FIG. 6 the curve and equilibrum conditions similar to those in FIG. 4 are shown with the pressure decreased to 0.01 millibar

In FIG. 7 an equilibrum curve for tantalum oxide and chlorine effects at a pressure of 10 millibar are shown over a range of temperatures.

In FIG. 8 the equilibrum curve for tantalum metal and hydrogen chloride are shown at 10 millibar over a range of temperatures.

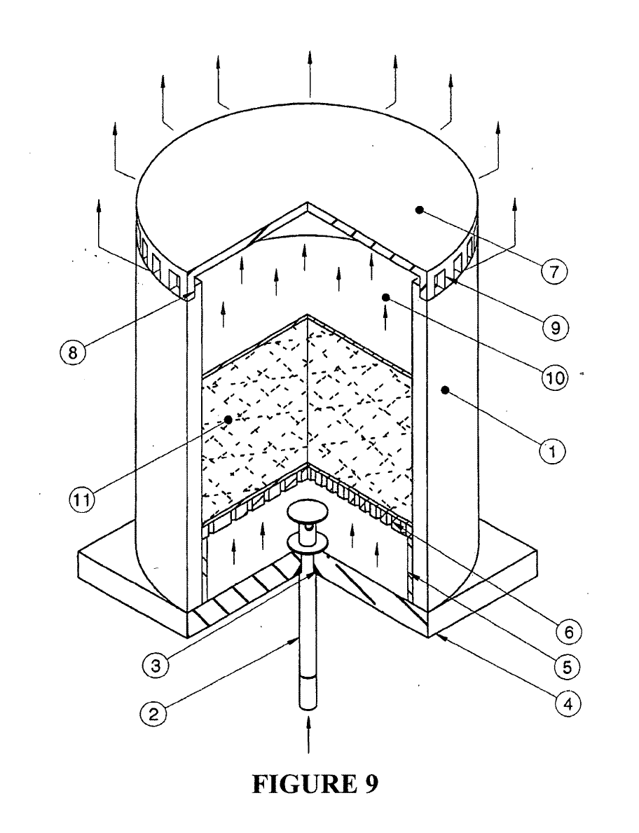

In FIG. 9 one view of the apparatus used to create the varied species of the method of the invention is shown.

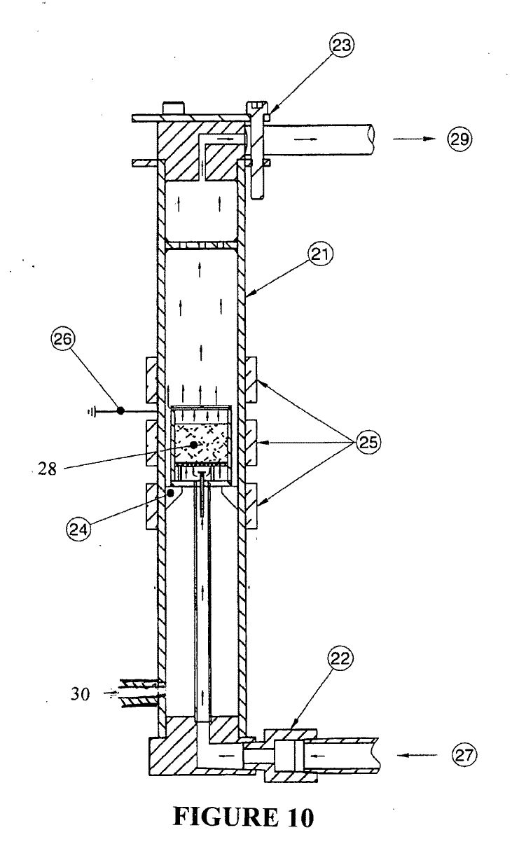

In FIG. 10 the apparatus is again shown, this time in the optimal elongated shape that insures longer contact with the fill.

### PREFERRED EMBODIMENT OF INVENTION

In the most preferred embodiment of this invention utilizes the equipment as shown in FIG. 9 where a reactor producing a metal halide gas (the halide reactor) is coupled to a CVD furnace where the metal halide sourced in the metal halide reactor is deposited upon a substrate. The halide reactor is a container formed from a cylinder of refractory materials such as alumina (shown as 1) in this case and a bottom or base 4 with a hole sized for an inlet tube 2 is fashioned and sealed with refractory cement 3 to this base 4 of the cylinder of alumina. It is noted that, while other variations of the equipment can be visualized, the elements described herein enable the steps of the method.

Within the alumina cylinder is placed a second alumina cylinder 5 of slightly smaller diameter than the inside diameter of the alumina cylinder and a height of less than 2 cm and upon this second inner cylinder is placed a perforated plate of ceramic materials 6.

A removable top plate of alumina 7 designed to fit within a groove 8 in the open end of the alumina cylinder is then fitted to the cylinder end, this plate having an offset or slots 9 which provide an outlet in fluid communication with the interior of the vessel.

The inlet tube is cemented with refractory cement to the base plate 4 end piece to form a vapor proof seal. The inside of the alumina cylinder is filled with metal pellets or granules 11 sized as to not fall through or plug the holes on the ceramic perforated plate.

The top 7 is placed upon the cylinder and it is sealed with a vapor proof seal. As a further example of this disclosure, shown in FIG. 10, an external outer housing for the invention is constructed from a pipe segment 21 that is at least 6 times the height of the cylinder. This pipe segment has a diameter that is sized to accommodate the ceramic/alumina filled cylinder as shown in FIG. 1 plus at least two centimeters of inside diameter and is placed centrally within a tube of a length sufficient to provide some cooling, typically a length of at least 6 times the height of the filled cylinder. The pipe segment has vacuum seals at both ends 22, 23 as are well known in the industry. This non-reactive ceramic/alumina cylinder, now converted to a filled container with metal fill (in this example the fill is chromium metal granules) placed upon standoffs mounted within the portion of pipe 24 so the cylinder is at the middle of the length of the pipe and centrally located within the pipe such that the axes of the pipe and the cylinder coincide. The pipe 21, longer than the height of the filled container, is the outer housing of this invention.

To the outer housing are bolted external heaters 25, extending beyond the height of the non-reactive cylinder which is located near the mid point location of the non-reactive cylinder length within the outer housing (i.e. the heaters extend along the cylinder at least the height of the cylinder plus beyond the cylinder height). The heaters are of high temperature construction well known to practitioners within the field. The heaters are controlled by a controller via the signal from a thermocouple in contact with the outer housing 26 within the heated area. Halogen containing gas is introduced at the bottom 27 and after reacting with the fill 28 in the non-reactive cylinder flows out of the reactor and into a CVD type furnace from 29.

In operation, the non-reactive container of the metal halide generator is switched to a nitrogen or inert gas purge. This purge enters through tube 30. As the purge is continuing, pressure is reduced to a millibar level. The heaters heat the vessel to over 1000 degrees C. then dry hydrogen chloride gas is introduced through a flow control into the vessel via the inlet tube 30. While high temperatures are indicated for formation of the favorable CrCl₂ species, the temperatures of formation may range from 675° C. for low (0.1 mb) to well over 1000° C. at 2 or more millibar. At a temperature of 1050 degrees C. the hydrogen chloride gas with inert carrier gas flows through the vessel, in contact with a large surface area of chromium fill. As the reactive HCl gas flows through the bed of chromium, which is supported within the vessel by a non-reactive grid, it reacts and forms chrome chlorides, CrCl₂, CrCl₃, and CrCl₄ (the species formed depending upon the temperature of the non-reactive vessel, the temperatures selected in this example are to maximize formation of CrCl₂). The chrome chlorides and the carrier gas are swept through the remaining bed of chrome metal and out of the vessel via outflow tube(s) that communicates with the entry to the deposition (CVD) furnace.

The deposition furnace is maintained at a lower temperature than the metal halide reaction which drives the deposition of metallic chromium on the parts within the furnace. A typical temperature of 950° C. provides adequate differential to drive the reaction to metal in presence of hydrogen gas. Usually a ΔT of 50° C. is enough to ensure a deposition although greater differentials increase the rates. Time of deposition in this 2 mb example is 4 to 24 hours depending on needed layer thickness with the deposition rates rapidly dropping off with time.

At the end of the CVD cycle the flow of chrome chlorides from the metal halide reactor are stopped by shutting off the flow of hydrogen chloride to the halide reactor and continuing an inert purge while the metal halide reactor external heaters are turned off so the temperature gradually is reduced to ambient. Temperatures in the deposition furnace are also reduced to ambient and then the halide reactor and the deposition furnace are brought to ambient pressure with inert gas purge. The halide reactor vessel may be stored at ambient temperatures under dry nitrogen gas for an indefinite period of time between uses.

In a second embodiment of the invention the chrome halide reactor in the above example is used at a minimal temperature of 775° C. which may allow the retention of hardness in some steels while the deposition furnace is maintained at a temperature of 725° C. Deposition time is 18 hours while other steps remain the same.

In a third embodiment of this invention, the steps in the first embodiment are followed by the purging of the halide reactor with inert gases at the end of the chrome deposition when the halogen containing gas is shut off at the halide reactor inlet. A separate supply of oxygen gas is introduced directly into the deposition furnace after purging metal halides but prior to the cooling of the deposition reactor thus forming a thin reacted surface layer of chromium oxide on the surface of the chromium metal deposition, providing a smooth, non-crystalline hard surface.

In a fourth embodiment of the invention, a metallic titanium layer is deposited upon a substrate.

The metal halide creating reactor described above is loaded with a charge of granular titanium metal which rests in several layers upon ceramic grids within the halide reactor.

The halide reactor is then closed and purged with hydrogen or an inert gas and will be evacuated at the same time as the deposition furnace.

A part cleaned in multiple solvents and multiply rinsed in deionized water is placed onto a platform within a deposition furnace, separate from the halide reactor, purged with inert gas or hydrogen and then evacuated to a pressure of 0.1 bar. Both the deposition furnace and the halide reactor, being interconnected, are jointly purged and evacuated.

The evacuated halide reactor is then heated by temperature controlled external heaters to a temperature of 1200 degrees C. while the deposition furnace is heated by its own temperature controlled external heaters to a temperature of approximately 700 degrees C. A low (under 15 l/hr) flow of inert gas continues to sweep the reactor and furnace. This volume is adjusted to insure flow as heatup continues.

Hydrogen chloride gas is introduced by injectors into the halide reactor where it reacts with the titanium metal to form a mix of halides with the species TiCl₂ predominate. To insure the creation of the TiCl₂ gas the hydrogen chloride gas is maintained at a starve feed level, at no more than ½ of the normal stoichiometric flow for the halide formation, while the temperature in the reactor is maintained at 1200° C. It is noted that the extended height to width shape of the reactor and the multiple levels of metallic fill promotes the starve feed of the hydrogen chloride and helps pust reactions towards the desired TiCl2 species. The metal halide gas generated by the reaction in the halide reactor is flowed into the deposition reactor along with an inert carrier gas and hydrogen gas where the external heaters of the deposition furnace are maintained such that the temperature in the deposition zone (around the part) are approximately 700 degrees C. This lower temperature causes a reaction between hydrogen gas and the metal halide producing a metal layer on the part and a hydrogen chloride gas compound that is exhausted from the furnace. The reaction takes considerable tuning of the process to accommodate the furnace and the target of metal formation tends to be a meta-stable area within the theoretical deposition curves.

In a fifth embodiment of the invention, a metallic titanium layer is deposited upon a substrate and then a further reaction causes an additional deposition of a layer of titanium nitride upon the metallic titanium surface.

The metal halide reactor is loaded with a charge of granular titanium metal which rests in several layers upon ceramic grids within the halide reactor.

The halide reactor is then closed and purged with an inert gas such as argon and is evacuated at the same time as the deposition furnace.

A cleaned part is placed onto a platform within a deposition furnace, separate from the halide reactor, purged with inert gas or hydrogen and then evacuated to a pressure of 0.1 bar. Both the deposition furnace and the halide reactor, being interconnected, are jointly purged and evacuated.

The evacuated halide reactor is then heated by temperature controlled external heaters to a temperature of 1200 degrees C. while the deposition furnace is heated by its own temperature controlled external heaters to a temperature of approximately 700 degrees C. A low (under 15 l/hr) flow of inert gas continues to sweep the reactor and furnace. This flow is adjusted to maintain a through flow at all times.

Hydrogen chloride gas is introduced by injectors into the halide reactor where it reacts with the titanium metal to form a mix of halides with the species TiCl₂ predominate. Gas generated by the reaction in the halide reactor is flowed into the deposition furnace along with an inert carrier gas and hydrogen gas where the external heaters of the deposition furnace are maintained such that the temperature in the deposition zone (around the part) are approximately 700 degrees C. This lower temperature causes a reversal of the metal/hydrogen chloride reaction in presence of excess hydrogen gas producing a metal layer on the part and a hydrogen chloride gas compound that is exhausted from the furnace.

The halide reactor and the deposition furnace are then cooled to approximately 625 degrees C. while inert gas purge removes the metal halide gases. Chlorine gas is then added to the halide reactor, forming TiCl₄ gas at the exist of this reactor and this gas flows into the deposition furnace where nitrogen gas, added with the purge gas mixes with the TiCl₄ gas and forms TiN at the surface of the parts in the deposition area of the deposition furnace. The deposition furnace is then purged and cooled, brought to ambient pressures and the parts are removed.

In a sixth embodiment, the metallic titanium layer is formed as in embodiment five but the steps in the fifth embodiment are followed by the purging of hydrogen at the end of the Titanium metal deposition when the hydrogen chloride gas is shut off at the halide reactor inlet and a separated supply of chlorine gas is introduced into the inlet of the halide reactor where it reacts with the titanium metal forming predominately the TiCl₄ species and this gas flows into the deposition furnace where separate supply of Boron tri-chloride (BCl₃) is introduced with hydrogen gas and thus forms a titanium boride on the metallic titanium that was formed with the TiCl₂ reaction in the prior steps. The input reactive gases are then shut off and the purging of the reactive gases starts prior to the cooling of the deposition furnace, releasing the vacuum after cooling and upon removal of the parts they have a metallic titanium layer under a TiB₂ layer. If the TiB₂ reaction is subject to plasma activation in the deposition furnace the deposition is further enhanced.

In a seventh embodiment, the apparatus in the co-pending application is employed with a fill of tantalum granules. The apparatus is evacuated and a first cleaning step is employed using Cl₂ gas at 720° C. to remove oxides from the tantalum metal fill and the reaction products are exhausted from the reactor. The reactor is purged with inert gases to remove all Cl₂ gas. The evacuated reactor is held at 400° C. and gaseous HCl is added to the metal fill. Reaction products are the TaCl₅ gas which flows into the fluidly communicating deposition furnace where a substrate at a temperature of 1000° C. facilitates the CVD deposition of the Ta metal and the hydrogen chloride gas is exhausted. The addition of H₂O in the cooling down of the furnace after the deposition enhances the development of the oxide layer although a thin layer would immediately form upon exposure to oxygen.

In an eighth embodiment of this invention a Ta disilicide layer is formed using the steps above but eliminating the H₂O and instead lowering the furnace temperature to 500° C. then purging the furnace with inert gas and then adding silane gas which reacts with the tantalum to form a TaSi₂ layer, then cooling the furnace, relieving the pressure and removing the coated parts.

It is noted that the gases within the group 7 of the periodic table (any halogen) are all useful in this invention The halogen, hydrogen halide, and mixed hydrogen halides or halogens and the metals that they react with are all apparent to the skilled practitioner within this field. It is further evident that, given the concept herein the shape, specific location, the steps and procedures, and the temperatures of this invention may be changed within a considerable range within these teachings.

Within the bounds of this invention the use of halogen compounds also includes the use of the interhalogen series of compounds such as ClF, BrCl, ICl, IBr, ClF₃, BrF₃, ICl₃, ClF₅, BrF₅, IF₅, and IF_{S}, as reactants in the generation furnace.

It is further noted that any metal fill selected from a group containing the elements Al, Cr, W, Mo, V, Zn, Mn, U, Nb. Ta, Al, Ga, Sn, Si, As, Bi, Be, and Zr are useful in this invention and that a wide variety of metal fill materials may substitute for the chromium or other metals noted as examples above. The use of halogen, hydrogen halide, and other halogen containing compounds as well as the metals that they react with are all apparent to the skilled practitioner within this field. It is further evident that, given the concept herein the shape, specific location and the temperatures of this invention may be changed within a considerable range within these teachings.

In this invention and its disclosure a large commercial size deposition furnace was used with a diameter of 1 meter and a height of 1.8 meters. Its high temperature heaters provided temperatures of up to 1600 degrees C. and vacuum levels down to 0.01 millibar. The extended precursor reactor was mounted on top of the deposition furnace with a tube connecting the two units. It should be noted that the conditions herein are usable in this particular furnace. Experience with lower temperature furnaces used in deep nitriding processes have shown that otherwise identical furnaces do perform somewhat differently so it is expected that use of this disclosure in other design furnaces will require fine tuning of the process but the basic steps will remain the same.

One skilled in the art will readily appreciate that the present invention is well adapted to carry out the objects and obtain the ends and advantages mentioned as well as those inherent therein or specifically mentioned. Practitioners will be aware that furnace construction, size, part fixturing and location, and many other factors will have an affect and the conditions herein are a guide but will require adaptation for each set of halide reactors and deposition furnaces. It will be apparent to those in the art that various modifications and variations can be made in practicing the present invention without departing from the spirit or scope of the invention. Changes therein and other uses will occur to those skilled in the art which are encompassed within the spirit of the invention as defined by the scope of the invention

I claim:

1. A method to deposit metal layers on a substrate with a chemical vapor deposition furnace system operated at vacuum levels between 100 and 0.01 millibar pressure where in a first stage, a first halogen containing gas passes from a first inlet port into a first reactor containing a metal fill and maintained at a first temperature where reactions between said halogen containing gas and said metal fill generates a metal halide gas at said first temperature, and where then, by fluid communicating means, said metal halide gas is transported to a stage within a second reactor or deposition furnace containing a deposition area which is at a second temperature different from said first temperature, and then, in the presence of hydrogen gas added by a second inlet flow means into said deposition furnace, said second temperature favors decomposition of said metal halide to an amorphous or microcrystalline metal layer on a substrate in said deposition area and the hydrogen halide gas formed in decomposition is exhausted from said deposition furnace.

2. The method to deposit metal layers in claim 1 where the first reactor is treated with a primary halogen gas or primary halogen containing compound or primary reactive gas, different from said halogen gas, halogen containing said compound or said reactive gas in claim 1 and then purged of said different primary halogen gas or primary halogen containing compound or primary reactive gas prior to said first stage generation of said metal halide to prepare the metal for reaction into metal halide gas in said first stage.

3. The method to deposit metal layers in claim 1 where said second or deposition furnace after said decomposition of said metal halide to an amorphous or microcrystalline layer said deposition furnace is purged with inert gas and then a different gaseous compound flows through an inlet in said deposition furnace into said deposition furnace by transport means and where said deposition furnace temperatures are changed to provide thermochemical driving means to create further deposition or reactions on said metal layers or metal compounds via surface reactions within said deposition reactor after said second stage.

4. The method to deposit metal layers in claim 1 where said metal of said metal halide is selected from a group containing the elements Al, Cr, W, Mo, V, Zn, Mn, U, Nb. Ta, Ga, Sn, Si, As, Bi, Be, and Zr.

5. The method to deposit metal layers in claim 1 where said first halogen containing gas is a halogen gas, halogen compound, mixture of halogen gases or an interhalogen compound where the halogen is selected from a group consisting of iodine, chlorine, bromine and fluorine or the hydrogen compounds or the interhalogen compounds of these halogens.

6. The method to deposit metal layers in claim in 1 where a flow control means located in fluid communication with said first inlet port controls the flow of said halogen gas, halogen compounds, or interhalogen compounds.

7. The method to deposit metal layers in claim in 6 where a purge gas is also introduced into said first inlet port or into said second inlet port of said second or deposition furnace.

8. The method to deposit metal layers in claim in 1 where a third inlet port into said deposition furnace is also in fluid communication with a source of measured flow of a purge gas which is used both when said deposition furnace is operating and when said deposition furnace is not being supplied with metal halide gas.

9. The method to deposit metal layers in claim in 1 where a purge gas source is supplied by purge gas supply means to said first reactor to remove said halogen or halogen containing gas prior to introduction of other gases or when said halogen gas flow is halted.

10. The method to deposit metal layers in claim in 1 where a flow control means located in fluid communication with said first inlet port controls the flow of said halogen gas or halogen compounds or interhalogen compounds from a reservoir or storage means containing said halogen gas or halogen compounds thus providing control means limiting stoichiometry of reactions within said first reactor.

11. The method to deposit metal layers in claim 1 where after the reaction of said gaseous metal halide in said deposition furnace, a purge of non-reactive gas entering said deposition furnace through purging means removes said metal halide and decomposition products of said reaction within said deposition furnace from said deposition furnace before a second reactive gaseous compound is introduced into said second reactor to further modify the surface of said metal layer.

12. A method to deposit a metal layer on a substrate using CVD processes at a vacuum of between 100 millibar and 0.01 milibar pressure where a first reactor is prepared with a precleaning step with introduction of chemical agents or a plasma field to remove oxides or unsuitable contaminants from a metal fill within said first reactor to prepare said metal fill then a halogen gas or a halogen containing compound different from said chemical agents is introduced through an inlet port into said first reactor which is at a first reactor temperature and then said halogen gas or halogen compound or interhalogen compound reacts with said metal fill to form a metal halide gas then said metal halide gas thus formed is then introduced into a second deposition furnace where hydrogen added by controlled flow addition to an inlet in said deposition furnace provides decomposition of said metal halide to metal, driven by thermodynamically favored decomposition of the metal halide at a temperature different from the temperature in said first reactor, occurs upon a substrate producing an amorphous or microcrystalline layer upon said substrate.

13. The method to deposit metal layers in claim 12 where after said precleaning stage in said first reactor, a purge of a non-reactive gas removes said chemical agents or any plasma decomposition products prior to the introduction of said halogen gas or said halogen compound into said first reactor.

14. The method to deposit metal layers in claim 12 where after the reaction of said gaseous metal halide in said second furnace, a purge of non-reactive gas removes said metal halide and decomposition products of said reaction within said deposition furnace from said decomposition furnace before said second gaseous compound is introduced into said decomposition furnace to further modify the surface of said metal layer.

15. The method to deposit metal layers in claim 12 where said inlet port is also in fluid communication with a source of measured flow of a purge gas which is used when said reactor is operating and when said reactor is not being supplied with halogen gas.

16. A method to deposit a metal layer on a substrate where a metal fill within a first reactor, controllably heated, has a halogen gas or a gaseous halide compound introduced into said first reactor forming a metal halide gas a temperature selected to preferentially form a quantity of a specific species of said gaseous metal halide then said gaseous metal halide gas is then fluidly transported into a second reactor where a controlled flow of a reactive gas and a controllably heated deposition stage contains a substrate and where within said second reactor, a temperature, different from said temperature of said first reactor of said deposition stage causes decomposition of said metal halide by thermodynamically driven decomposition of said metal halide to form an amorphous or microcrystalline metal layer upon said substrate.

17. The method to deposit a metal layer on a substrate in claim 16 where after the reaction of said gaseous metal halide in said second reactor, a purge of non-reactive gas removes said metal halide and decomposition products of said reaction from said second reactor before a second gaseous compound is introduced into said second reactor to further modify the surface of the metal layer.
